(19) United States
(12) Patent Application Publication
(10) Pub. No.: US 2025/0203865 A1
(43) Pub. Date: Jun. 19, 2025

(54) THREE-DIMENSIONAL MEMORY DEVICE AND MANUFACTURING METHOD THEREOF

(71) Applicant: SK hynix Inc., Icheon-si Gyeonggi-do (KR)

(72) Inventors: Rho Gyu KWAK, Icheon-si Gyeonggi-do (KR); In Su PARK, Icheon-si Gyeonggi-do (KR); Na Yeong YANG, Icheon-si Gyeonggi-do (KR); Jung Shik JANG, Icheon-si Gyeonggi-do (KR); Seok Min CHOI, Icheon-si Gyeonggi-do (KR); Won Geun CHOI, Icheon-si Gyeonggi-do (KR)

(73) Assignee: SK hynix Inc., Icheon-si Gyeonggi-do (KR)

(21) Appl. No.: 18/675,578

(22) Filed: May 28, 2024

(30) Foreign Application Priority Data
Dec. 13, 2023 (KR) 10-2023-0180819

(51) Int. Cl. H10B 43/27; H10B 43/10; H10B 43/40

(52) U.S. Cl. CPC H10B 43/27; H10B 43/10; H10B 43/40

(57) ABSTRACT

In an embodiment of the disclosed technology, a three-dimensional memory device includes a stack including a plurality of gate electrodes, each of which includes an electrode portion and a pad portion, the pad portion being disposed on one area of the electrode portion, and a plurality of interlayer insulating layers that are stacked alternately with the plurality of gate electrodes, the stack having a connection area in which the pad portions of the plurality of gate electrodes are disposed in step shapes; a row connection contact passing through the connection area and passing through a corresponding pad portion of a corresponding gate electrode, among the plurality of gate electrodes, thereby connecting to the corresponding pad portion of the corresponding gate electrode; and a plurality of first insulating patterns disposed between the row connection contact and side surfaces of electrode portions of gate electrodes that face the row connection contact.

### CROSS-REFERENCE TO RELATED APPLICATION

The present application claims priority under 35 U.S.C. § 119(a) to Korean Patent Application No. 10-2023-0180819 filed in the Korean Intellectual Property Office on Dec. 13, 2023, which application is incorporated herein by reference in its entirety.

### BACKGROUND

### 1. Technical Field

Various embodiments of the disclosed technology generally relate to a semiconductor technology, and more particularly, to a three-dimensional memory device and a manufacturing method thereof.

### 2. Related Art

A three-dimensional memory device including memory cells which are three-dimensionally arranged has been proposed. The three-dimensional memory device has advantages in that a larger capacity may be realized within the same area by increasing the number of stacks through stacking memory cells in a vertical direction, thereby providing high performance and excellent power efficiency.

### SUMMARY

In an embodiment, a three-dimensional memory device may include: a stack including a plurality of gate electrodes, each of which includes an electrode portion and a pad portion, the pad portion being disposed on one area of the electrode portion, and a plurality of interlayer insulating layers that are stacked alternately with the plurality of gate electrodes, the stack having a connection area in which the pad portions of the plurality of gate electrodes are disposed in step shapes; a row connection contact passing through the connection area and passing through a corresponding pad portion of a corresponding gate electrode, among the plurality of gate electrodes, thereby connecting to the corresponding pad portion of the corresponding gate electrode; and a plurality of first insulating patterns disposed between the row connection contact and side surfaces of electrode portions of gate electrodes that face the row connection contact.

In an embodiment, a method for manufacturing a three-dimensional memory device may include: forming a pre-stack by alternately stacking a plurality of interlayer insulating layers and a plurality of sacrificial layers; forming a stairway structure in the pre-stack; forming a plurality of sacrificial patterns on upper surfaces of the stairway structure; forming a plurality of first holes that pass through the sacrificial patterns and the pre-stack; selectively forming a plurality of first insulating patterns on side surfaces of the plurality of sacrificial layers that are exposed due to the plurality of first holes; and forming a plurality of gate electrodes by replacing the plurality of sacrificial layers and the plurality of sacrificial patterns through the plurality of first holes with an electrode material and forming a plurality of row connection contacts in the plurality of first holes.

In an embodiment, a three-dimensional memory device may include: a first semiconductor structure including a peripheral circuit; and a second semiconductor structure disposed on the first semiconductor structure, the second semiconductor structure including: a source plate disposed on the first semiconductor structure; a stack disposed on the source plate, the stack including a plurality of gate electrodes, each of which includes an electrode portion and a pad portion, the pad portion being disposed on one area of the electrode portion, and a plurality of interlayer insulating layers that are stacked alternately with the plurality of gate electrodes, the stack having a connection area in which the pad portions of the plurality of gate electrodes are disposed in step shapes; a row connection contact passing through the connection area and passing through a corresponding pad portion of a corresponding gate electrode, among the plurality of gate electrodes, thereby connecting to the corresponding pad portion of the corresponding gate electrode; and a plurality of first insulating patterns disposed between the row connection contact and side surfaces of electrode portions of gate electrodes that face the row connection contact.

In an embodiment, a three-dimensional memory device may include: a first semiconductor structure having a peripheral circuit and a first bonding layer including a plurality of first bonding pads that are connected to the peripheral circuit; and a second semiconductor structure bonded to the first semiconductor structure, the second semiconductor structure including: a second bonding layer including a plurality of second bonding pads that are bonded to the plurality of first bonding pads; a stack disposed on the second bonding layer, the stack including a plurality of gate electrodes, each of which includes an electrode portion and a pad portion, the pad portion being disposed on one area of the electrode portion and a plurality of interlayer insulating layers that are stacked alternately with the plurality of gate electrodes, the stack having a connection area in which the pad portions of the plurality of gate electrodes are disposed in step shapes; a row connection contact passing through the connection area and passing through a corresponding pad portion of a corresponding gate electrode, among the plurality of gate electrodes, thereby connecting to the corresponding pad portion of the corresponding gate electrode; and a plurality of first insulating patterns disposed between the row connection contact and side surfaces of electrode portions of gate electrodes that face the row connection contact.

### BRIEF DESCRIPTION OF THE DRAWINGS

FIG. 1 is a plan view illustrating a part of a three-dimensional memory device based on an embodiment of the disclosed technology.

FIG. 2 is a cross-sectional view taken along the lines A-A′ and B-B′ of FIG. 1.

FIG. 3 is a cross-sectional view taken along the line C-C′ of FIG. 1.

FIG. 4 is an enlarged view of a part P1 of FIG. 2.

FIG. 5 is an enlarged view of a part P2 of FIG. 2.

FIG. 6 is an enlarged view of a part P3 of FIG. 2.

FIGS. 7A to 7H are views illustrating a method for manufacturing a three-dimensional memory device based on an embodiment of the disclosed technology.

FIGS. 8 and 9 are cross-sectional views illustrating three-dimensional memory devices based on embodiments of the disclosed technology.

### DETAILED DESCRIPTION

In the following description, the same elements will be designated by the same reference numerals although they are shown in different drawings. Further, in the following description of the present disclosure, a detailed description of known functions and configurations incorporated herein will be omitted when it may make the subject matter of the present disclosure rather unclear. It is to be noticed that the terms “comprising,” “having,” “including” and so on, used in the description and claims, should not be interpreted as being restricted to the means listed thereafter unless specifically stated otherwise. Where an indefinite or definite article is used when referring to a singular noun, e.g., “a,” “an” and “the,” this may include a plural of that noun unless specifically stated otherwise.

Also, in describing the components of the disclosure, there may be terms used like first, second, A, B, (a), and (b). These are solely for the purpose of differentiating one component from another component but do not limit the substances, order, sequence or number of the components.

In descriptions for the positional relationships of components, in the case where it is described that at least two components are “connected,” “coupled” or “linked,” it is to be understood that the at least two components may be directly “connected,” “coupled” or “linked” but may be indirectly “connected,” “coupled” or “linked” with another component interposed between the two components. Here, another component may be included in at least one of the at least two components which are “connected,” “coupled” or “linked” with each other.

In descriptions for time flow relationships of components, an operating method or a fabricating method, in the case where pre and post relationships in terms of time or pre and post relationships in terms of flow are described, for example, by “after,” “following,” “next” or “before,” non-continuous cases may be included unless “immediately” or “directly” is used.

In the case where a numerical value for a component or its corresponding information is mentioned, even though there is no separate explicit description, the numerical value or its corresponding information can be interpreted as including an error range that may be caused by various factors (for example, a process variable, an internal or external shock, noise, etc.).

Hereinafter, various embodiments of the disclosed technology will be described in detail with reference to the accompanying drawings.

Various embodiments of the disclosed technology are directed to suggesting a three-dimensional memory device which includes a contact passing through gate electrodes, and a manufacturing method thereof.

According to the embodiments of the disclosed technology, a row connection contact which passes through gate electrodes may be easily connected to a corresponding gate electrode.

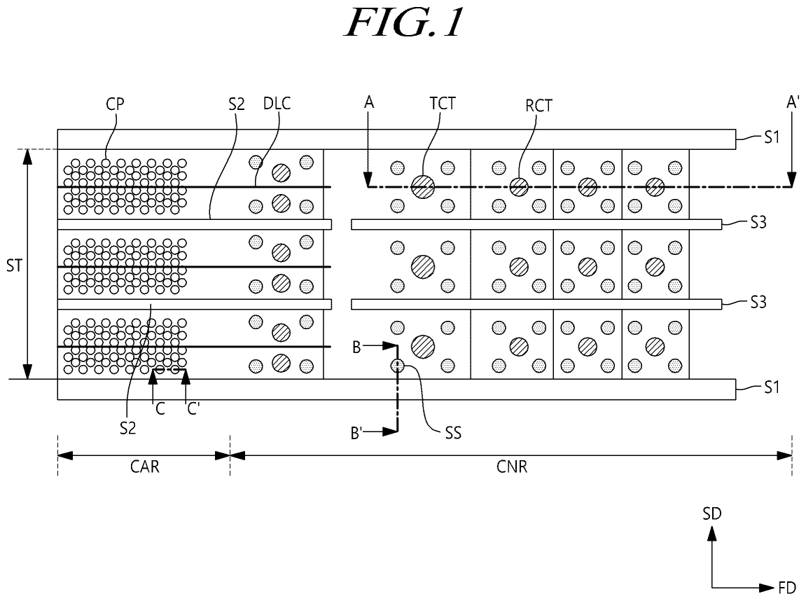

FIG. 1 is a schematic plan view of a three-dimensional memory device based on an embodiment of the disclosed technology.

Referring to FIG. 1, the three-dimensional memory device based on the embodiment of the disclosed technology may include a stack ST. The stack ST may include a cell area CAR and a connection area CNR that extends from the cell area CAR.

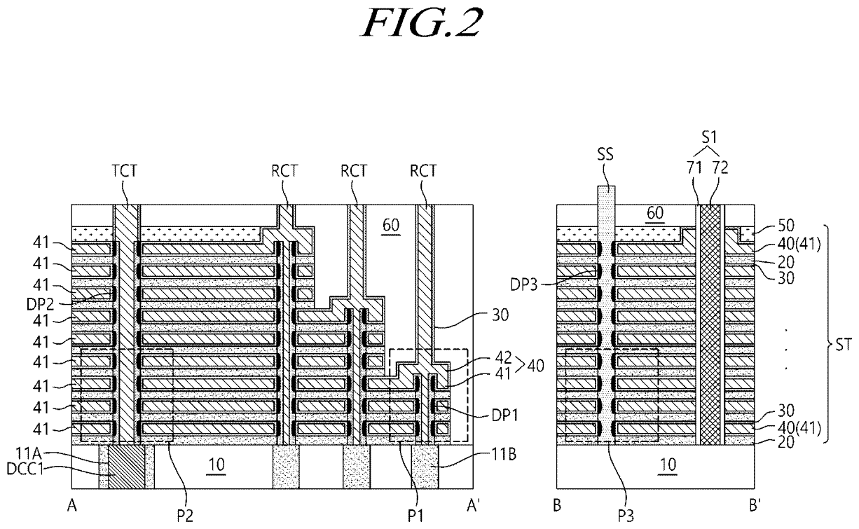

As will be described later with reference to FIG. 2, the stack ST may include a plurality of gate electrodes that are vertically stacked. The plurality of gate electrodes may include a plurality of word lines and select lines. The select lines may include a drain select line and a source select line.

First isolation patterns S1 may be disposed on both sides of the stack ST. The first isolation patterns S1 may extend in a first direction FD and may be adjacent to each other in a second direction SD, the second direction SD being intersecting the first direction FD. The first direction FD and the second direction SD may intersect perpendicularly to each other. The first direction FD may be the extending direction of word lines, and the second direction SD may be the extending direction of bit lines. The stack ST may be stacked in a third direction that is perpendicular to both the first direction FD and the second direction SD. The term “vertically” may refer to the third direction.

Although only two first isolation patterns S1 and one stack ST are illustrated in the drawing, a plurality of stacks may be arranged in the second direction SD, and the first isolation pattern S1 may be disposed between two stacks that are adjacent to each other to isolate the stacks.

Second and third isolation patterns S2 and S3 and drain select line cuts DLC may be configured in the stack ST. The second isolation patterns S2 and the drain select line cuts DLC may extend from the cell area CAR to the connection area CNR in the first direction FD. The second isolation patterns S2 may vertically pass through the stack ST. The drain select line cut DLC may be disposed between adjacent drain select lines. Drain select lines may be isolated from each other due to the second isolation patterns S2 and the drain select line cuts DLC.

The third isolation patterns S3 may vertically pass through the stack ST. The third isolation patterns S3 may extend in the first direction FD in the connection area CNR.

A plurality of row connection contacts RCT may vertically pass through the connection area CNR of the stack ST. Each row connection contact RCT may be connected to a corresponding gate electrode to transfer an operating voltage to the gate electrode.

A plurality of through contacts TCT may vertically pass through the stack ST. The through contact TCT may provide a vertical interconnection, which vertically passes through a three-dimensional memory cell array, to contribute to decreasing a metal level and reducing a die size. Although FIG. 1 illustrates that the through contact TCT passes through the connection area CNR of the stack ST, the position of the through contact TCT is not limited thereto. Although not illustrated, the through contact TCT may pass through the cell area CAR of the stack ST.

Supports SS may vertically pass through the stack ST. The supports SS may serve to support the stack ST to prevent the stack ST from collapsing or bending.

A plurality of cell plugs CP may vertically pass through the cell area CAR of the stack ST. The plurality of cell plugs CP may be disposed in a plurality of rows in the second direction SD. Each odd-numbered row of Cell plugs CP may be offset in the same first direction FD from even-numbered row of cell plugs CP. Due to this fact, a greater number of cell plugs CP may be disposed within the same area.

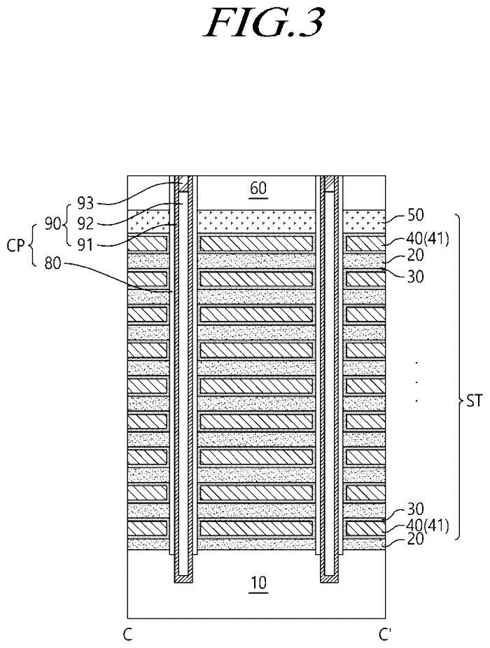

FIG. 2 is a cross-sectional view taken along the lines A-A′ and B-B′ of FIG. 1, and FIG. 3 is a cross-sectional view taken along the line C-C′ of FIG. 1.

Referring to FIGS. 2 and 3, the stack ST may include a plurality of interlayer insulating layers 20 and a plurality of gate electrodes 40 that are alternately stacked on a source plate 10.

Each of the plurality of gate electrodes 40 may include an electrode portion 41 and a pad portion 42, the pad portion 42 being disposed on one area of the electrode portion 41. The electrode portion 41 may extend from the cell area CAR to the connection area CNR of the stack ST. In the connection area CNR, the ends of the electrode portions 41 of the gate electrodes 40 may be disposed in step shapes. Specifically, referring to FIG. 2, a descending step shape may be formed when viewed from left to right. The pad portion 42 may be disposed on the end of the electrode portion 41. In the connection area CNR, as the pad portions 42 of the gate electrodes 40 are disposed in step shapes, a stairway structure may be configured to ascend when viewed from left to right.

The gate electrodes 40 may include a plurality of word lines, a source select line and a drain select line. For example, at least one gate electrode 40 from a lowermost layer, among the plurality of gate electrodes 40, may be used as the source select line, at least one gate electrode 40 from an uppermost layer, among the plurality of gate electrodes 40, may be used as the drain select line, and gate electrodes 40 between the source select line and the drain select line may be used as the word lines.

The gate electrodes 40 may include a conductive material. For example, the gate electrodes 40 may include tungsten (W). The interlayer insulating layers 20 may include silicon oxide.

An insulating layer 60 may be defined on the stack ST to cover the stack ST. The insulating layer 60 may include oxide. Apart from the stairway structure portion of the stack ST, a sacrificial pattern 50 may be disposed between the stack ST and the insulating layer 60. The sacrificial pattern 50 may include an insulating material that has an etch selectivity that is different from those of the interlayer insulating layers 20 and the insulating layer 60. For example, the sacrificial pattern 50 may include SiCN.

The cell plugs CP may extend to the source plate 10 by vertically passing through the insulating layer 60, the sacrificial pattern 50, and the stack ST. The cell plug CP may include a memory pattern 80 and a channel structure 90.

Although not illustrated, the memory pattern 80 may include a tunnel insulating layer, a data storage layer, and a first blocking insulating layer. The tunnel insulating layer may extend along the surface of the channel structure 90 and may include an insulating material capable of charge tunneling. The data storage layer may extend along the surface of the channel structure 90 with the tunnel insulating layer interposed therebetween. The data storage layer may include a material layer capable of storing data that is changed using Fowler-Nordheim tunneling. For example, the data storage layer may include a nitride layer capable of charge trapping, but the data storage layer is not limited thereto. The data storage layer may include a phase change material, nanodots, etc. The first blocking insulating layer may extend along the surface of the channel structure 90 with the tunnel insulating layer and the data storage layer interposed therebetween. The first blocking insulating layer may include an insulating material capable of blocking the movement of charges.

The channel structure 90 may include a cell channel layer 91, a core insulating pattern 92, and a capping pattern 93. The cell channel layer 91 may be used as the channel of a memory cell string. The cell channel layer 91 may be disposed on the memory pattern 80 and may be formed of a semiconductor material. For example, the cell channel layer 91 may include silicon. The core insulating pattern 92 and the capping pattern 93 may fill the central area of the channel structure 90. The core insulating pattern 92 may include oxide. The capping pattern 93 may be disposed on the core insulating pattern 92 and may include a sidewall that is surrounded by the upper end portion of the cell channel layer 91. The capping pattern 93 may include a doped semiconductor layer that includes at least one of an n-type impurity and a p-type impurity.

The plurality of row connection contacts RCT may vertically pass through the insulating layer 60 and the stack ST. Each row connection contact RCT may pass through the pad portion 42 and the electrode portion 41 of one gate electrode 40, among the plurality of gate electrodes 40, and may pass through the electrode portions 41 of gate electrodes 40 that are positioned under the one gate electrode 40. The row connection contact RCT may be connected to the pad portion 42 of the one gate electrode 40 and may be formed integrally with the one gate electrode 40.

First insulating patterns DP1 may be disposed between the row connection contact RCT and the side surfaces of the electrode portions 41 of gate electrodes 40 facing the row connection contact RCT. The row connection contact RCT may be electrically isolated from the gate electrodes 40 under the one gate electrode 40 by the first insulating patterns DP1.

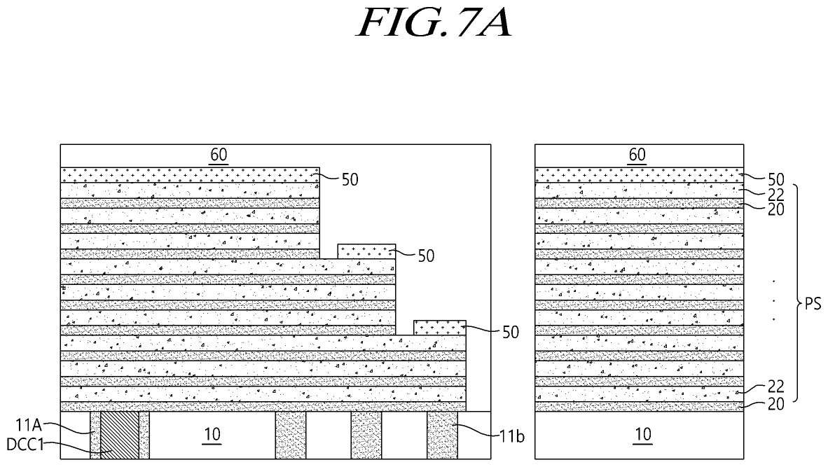

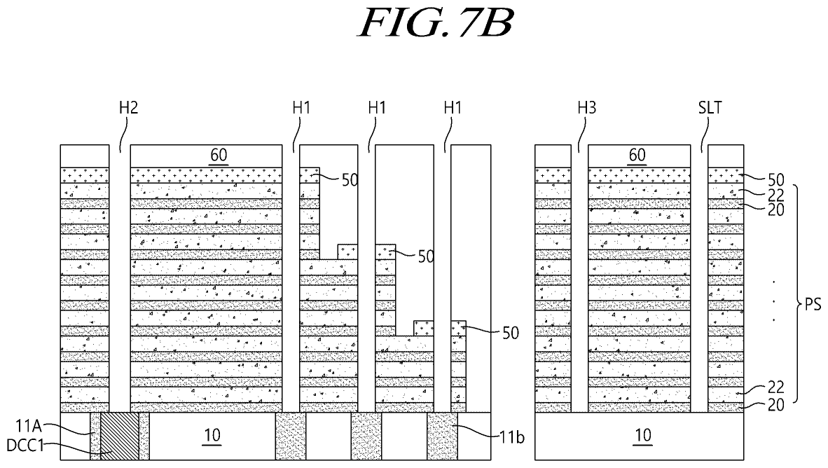

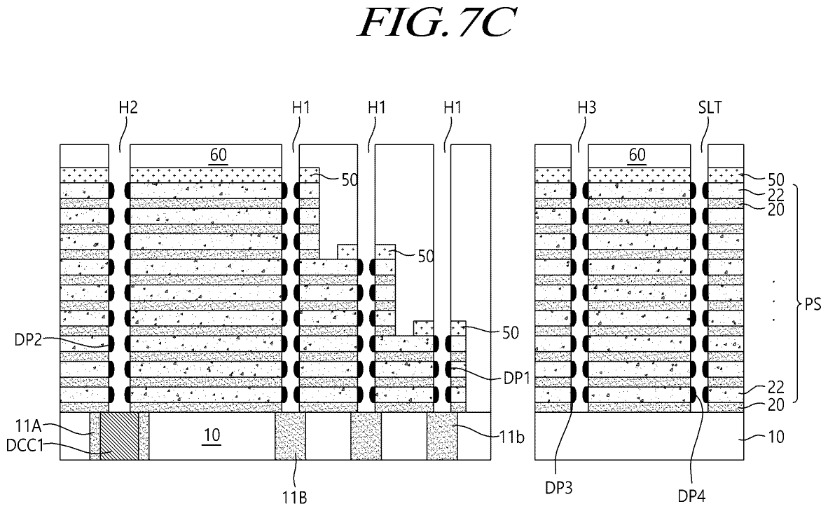

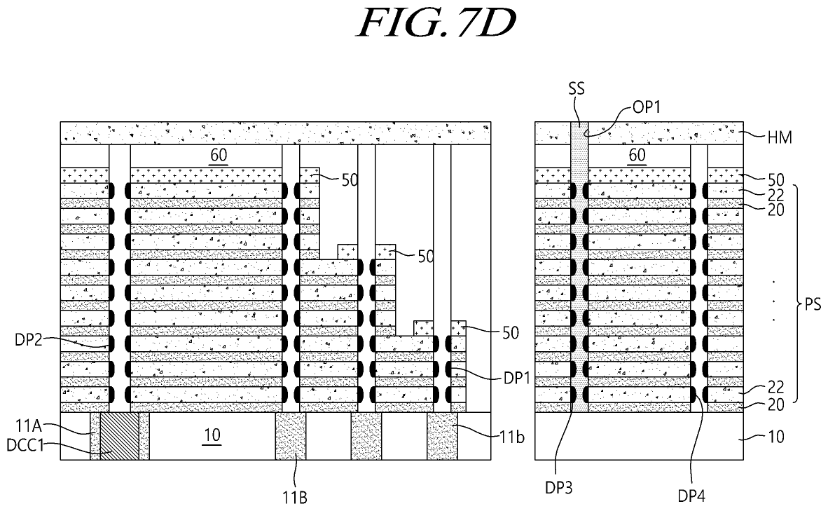

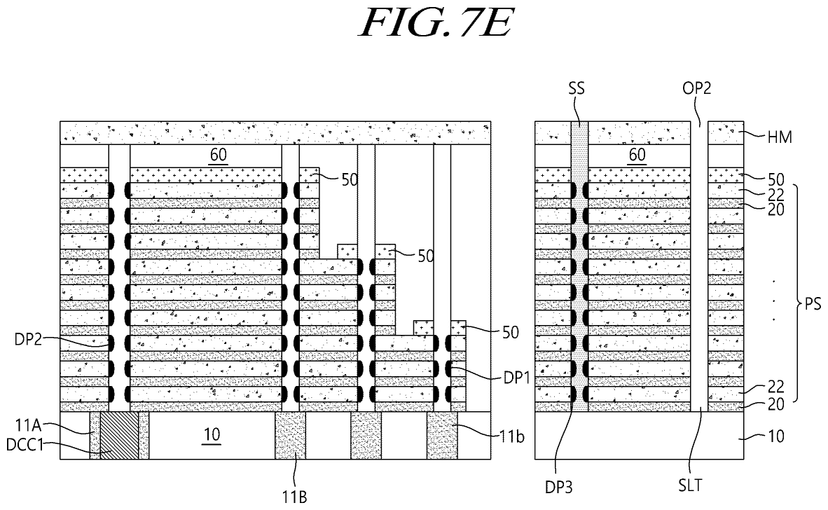

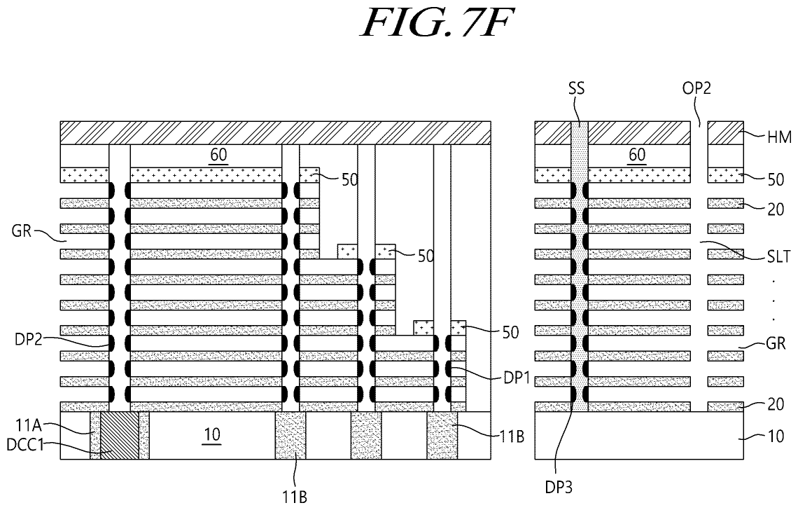

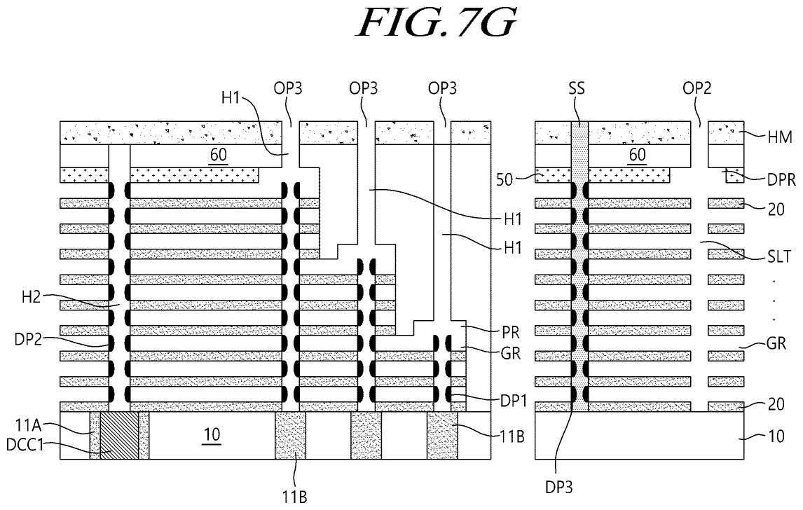

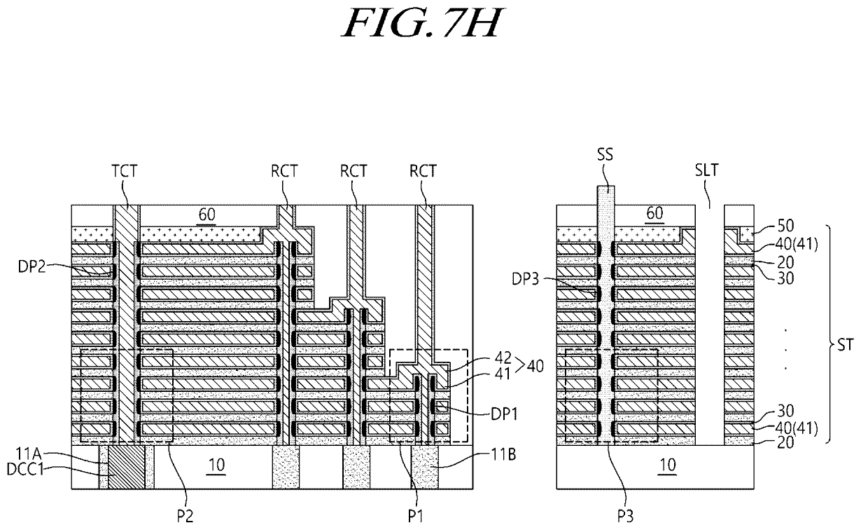

The row connection contacts RCT may be made of the same material as the gate electrodes 40. As will be described later with reference to FIG. 7H, the row connection contacts RCT may be formed together with the gate electrodes 40 in a process of forming the gate electrodes 40. Accordingly, a material forming the row connection contacts RCT may be the same as a material forming the gate electrodes 40.

As will be described later with reference to FIG. 7C, the first insulating patterns DP1 may be selectively deposited on sacrificial layers 22 and may be made of an insulating material that has an etch selectivity that is different from those of the sacrificial layers 22 and sacrificial patterns 50. For example, the first insulating patterns DP1 may be made of SiOC.

The through contact TCT may vertically pass through the insulating layer 60, the sacrificial pattern 50, and the stack ST. The through contact TCT may pass through the electrode portions 41 of the gate electrodes 40.

Second insulating patterns DP2 may be disposed between the through contact TCT and the side surfaces of the electrode portions 41 of the gate electrodes 40 facing the through contact TCT. The through contact TCT may be electrically isolated from the gate electrodes 40 due to the second insulating patterns DP2.

The through contact TCT may be made of the same material as the row connection contacts RCT and the gate electrodes 40. As will be described later with reference to FIG. 7H, the through contact TCT may be formed together with the row connection contacts RCT and the gate electrodes 40 in the process of forming the row connection contacts RCT and the gate electrodes 40. Accordingly, a material forming the through contact TCT may be the same as a material forming the row connection contacts RCT and the gate electrodes 40.

The second insulating patterns DP2 may be made of the same material as the first insulating patterns DP1. As will be described later with reference to FIG. 7C, the second insulating patterns DP2 may be formed together with the first insulating patterns DP1 in a process of forming the first insulating patterns DP1. Accordingly, a material forming the second insulating patterns DP2 may be the same as a material forming the first insulating patterns DP1.

The support SS may vertically pass through the insulating layer 60, the sacrificial pattern 50, and the stack ST. The support SS may pass through the electrode portions 41 of the gate electrodes 40.

The support SS may include an insulating material that has an etch selectivity that is different from those of a hard mask layer HM, to be described later with reference to FIG. 7D, and the sacrificial layers 22. The support SS may be configured with a single layer. Although not illustrated, in another embodiment, the support SS may include a liner layer and a filling layer. The liner layer may extend along the surface of the support SS, and the filling layer may be disposed in the central area of the support SS. The liner layer may include nitride, and the filling layer may include oxide.

Third insulating patterns DP3 may be disposed between the support SS and the side surfaces of the electrode portions 41 of the gate electrodes 40 facing the support SS.

The third insulating patterns DP3 may be made of the same material as the first and second insulating patterns DP1 and DP2. As will be described later with reference to FIG. 7C, the third insulating patterns DP3 may be formed together with the first and second insulating patterns DP1 and DP2 in the process of forming the first and second insulating patterns DP1 and DP2. Accordingly, a material forming the third insulating patterns DP3 may be the same as a material forming the first and second insulating patterns DP1 and DP2.

A second blocking insulating layer 30 may be formed along the surfaces of the gate electrodes 40, the row connection contacts RCT, the through contact TCT, and the first and second insulating patterns DP1 and DP2. The second blocking insulating layer 30 may surround the outer surfaces of the gate electrode 40 and the row connection contact RCT, which are integrally formed. The second blocking insulating layer 30 may include an insulating material that has a dielectric constant that is higher than that of the first blocking insulating layer of the memory pattern 80. For example, the first blocking insulating layer may include silicon oxide, and the second blocking insulating layer 30 may include metal oxide, such as aluminum oxide.

The first isolation pattern S1 may vertically pass through the insulating layer 60 and the stack ST. The first isolation pattern S1 may include a side insulating layer 71 and a conductive vertical contact 72. The conductive vertical contact 72 may be disposed in the central area of the first isolation pattern S1. The conductive vertical contact 72 may be insulated from the plurality of gate electrodes 40 due to the side insulating layer 71. The conductive vertical contact 72 may include a doped semiconductor layer. The conductive vertical contact 72 may be used as a common source line.

Openings may be defined in the source plate 10, and insulating patterns 11A and 11B may be disposed in the openings. A first conductive contact plug DCC1, which passes through the insulating pattern 11A, may be formed under the through contact TCT to be connected to the through contact TCT. Although the disclosed technology illustrates a case in which a conductive contact plug that is connected to the row connection contact RCT is not configured, if necessary, a conductive contact plug that passes through the insulating pattern 11B may be formed under the row connection contact RCT to be connected to the row connection contact RCT.

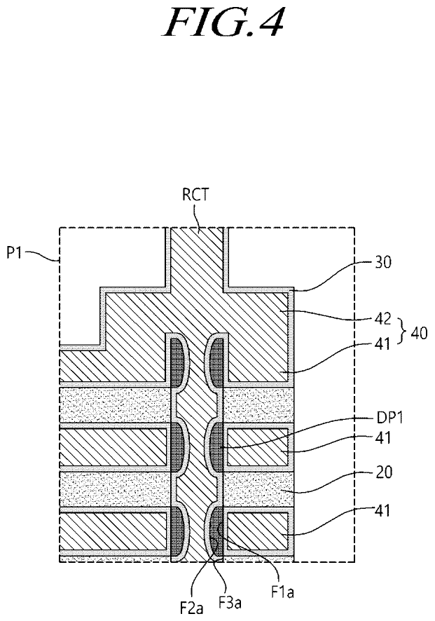

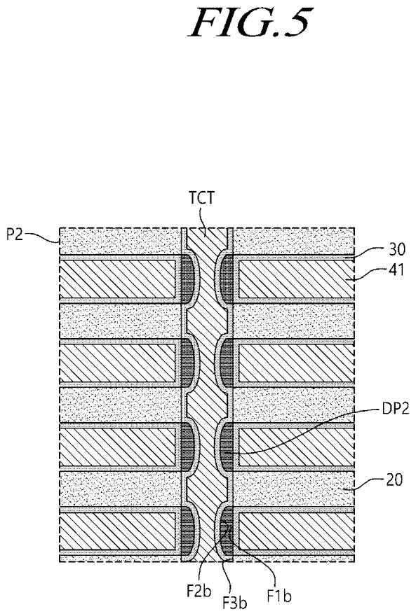

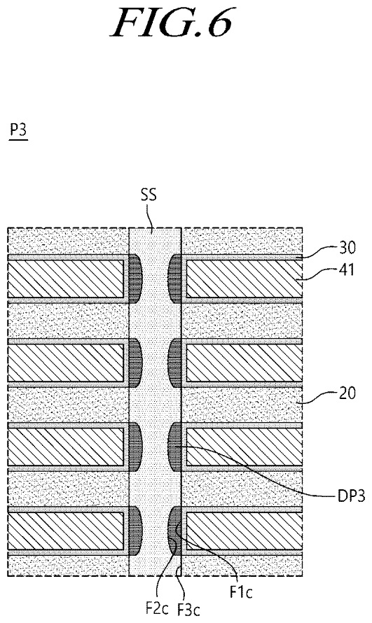

FIG. 4 is an enlarged view of a part P1 of FIG. 2, FIG. 5 is an enlarged view of a part P2 of FIG. 2, and FIG. 6 is an enlarged view of a part P3 of FIG. 2.

Referring to FIG. 4, the first insulating pattern DP1 may have a first surface F1a that faces the electrode portion 41 and a second surface F2a that faces the row connection contact RCT. The interlayer insulating layer 20 may have a first side surface F3a that faces the row connection contact RCT. The first surface F1a of the first insulating pattern DP1 may be aligned with first side surfaces F3a of the interlayer insulating layers 20.

As will be described later with reference to FIGS. 7B and 7C, a first hole H1 that passes through the plurality of interlayer insulating layers 20 and the plurality of sacrificial layers 22, which are alternately stacked, may be formed, and the first insulating patterns DP1 may be formed on the side surfaces of the sacrificial layers 22, which are defined by the first hole H1.

Referring again to FIG. 4, the first side surfaces F3a of the interlayer insulating layers 20 may be surfaces that are defined by the first hole H1 (see FIG. 7B). The first side surfaces F3a of the interlayer insulating layers 20 may be disposed on the same surface as the side surfaces of the sacrificial layers 22 (see FIG. 7B) on which the first insulating patterns DP1 are formed. Accordingly, the first surfaces F1a of the first insulating patterns DP1 may be aligned with the first side surfaces F3a of the interlayer insulating layers 20. The second surface F2a of the first insulating pattern DP1 may include a curved surface.

The second blocking insulating layer 30 may be disposed between the first surface F1a of the first insulating pattern DP1 and the electrode portion 41. The second blocking insulating layer 30 may be disposed between the second surface F2a of the first insulating pattern DP1 and the row connection contact RCT. The second blocking insulating layer 30 may be disposed between the first side surfaces F3a of the interlayer insulating layers 20 and the row connection contact RCT.

Referring to FIG. 5, the second insulating pattern DP2 may have a first surface F1b that faces the electrode portion 41 and a second surface F2b that faces the through contact TCT. The interlayer insulating layer 20 may have a second side surface F3b that faces the through contact TCT. The first surfaces F1b of the second insulating patterns DP2 may be aligned with the second side surfaces F3b of the interlayer insulating layers 20.

As will be described later with reference to FIGS. 7B and 7C, a second hole H2 that passes through the plurality of interlayer insulating layers 20 and the plurality of sacrificial layers 22, which are alternately stacked, may be formed, and the second insulating patterns DP2 may be formed on the side surfaces of the sacrificial layers 22, which are defined by the second hole H2.

Referring again to FIG. 5, the second side surfaces F3b of the interlayer insulating layers 20 may be surfaces that are defined by the second hole H2 (see FIG. 7B). The second side surfaces F3b of the interlayer insulating layers 20 may be disposed on the same surface as the side surfaces of the sacrificial layers 22 (see FIG. 7B) on which the second insulating patterns DP2 are formed. Accordingly, the first surfaces F1b of the second insulating patterns DP2 may be aligned with the second side surfaces F3b of the interlayer insulating layers 20. The second surface F2b of the second insulating pattern DP2 may include a curved surface.

The second blocking insulating layer 30 may be disposed between the first surface F1b of the second insulating pattern DP2 and the electrode portion 41. The second blocking insulating layer 30 may be disposed between the second surface F2b of the second insulating pattern DP2 and the through contact TCT. The second blocking insulating layer 30 may be disposed between the second side surfaces F3b of the interlayer insulating layers 20 and the through contact TCT.

Referring to FIG. 6, the third insulating pattern DP3 may have a first surface F1c that faces the electrode portion 41 and a second surface F2c that faces the support SS. The interlayer insulating layer 20 may have a third side surface F3c that faces the support SS. The first surfaces F1c of the third insulating patterns DP3 may be aligned with the third side surfaces F3c of the interlayer insulating layers 20.

As will be described later with reference to FIGS. 7B and 7C, a third hole H3 that passes through the plurality of interlayer insulating layers 20 and the plurality of sacrificial layers 22, which are alternately stacked, may be formed, and the third insulating patterns DP3 may be formed on the side surfaces of the sacrificial layers 22, which are defined by the third hole H3.

Referring again to FIG. 6, the third side surfaces F3c of the interlayer insulating layers 20 may be surfaces that are defined by the third hole H3 (see FIG. 7B). The third side surfaces F3c of the interlayer insulating layers 20 may be disposed on the same surface as the side surfaces of the sacrificial layers 22 (see FIG. 7B) on which the third insulating patterns DP3 are formed. Accordingly, the first surfaces F1c of the third insulating patterns DP3 may be aligned with the third side surfaces F3c of the interlayer insulating layers 20. The second surface F2c of the third insulating pattern DP3 may include a curved surface.

The second blocking insulating layer 30 may be disposed between the first surface F1c of the third insulating pattern DP3 and the electrode portion 41. The second blocking insulating layer 30 might not be disposed between the second surface F2c of the third insulating pattern DP3 and the support SS and between the third side surfaces F3c of the interlayer insulating layers 20 and the support SS.

Hereinafter, a method for manufacturing a three-dimensional memory device based on an embodiment of the disclosed technology will be described.

FIGS. 7A to 7H are views illustrating a method for manufacturing a three-dimensional memory device based on an embodiment of the disclosed technology.

Referring to FIG. 7A, a plurality of interlayer insulating layers 20 and a plurality of sacrificial layers 22 may be alternately stacked on a source plate 10. The interlayer insulating layers 20 may include silicon oxide. The sacrificial layers 22 may include a material that has an etch selectivity that is different from that of the interlayer insulating layers 20, for example, nitride, such as silicon nitride.

Thereafter, by patterning the interlayer insulating layers 20 and the sacrificial layers 22, a pre-stack PS may be formed. The pre-stack PS may have step shapes. Hereinafter, a portion having a step shape may be referred to as a step portion. A step may be defined as a portion that is not covered by an upper layer and is thus exposed in the step portion. The step may include an upper step surface and a vertical sidewall that is connected to the upper step surface, the vertical sidewall extending downward from the upper step surface.

Thereafter, by conformally forming a sacrificial material layer on the pre-stack PS and patterning the sacrificial material layer, sacrificial patterns 50 may be formed on the upper surfaces of steps (upper step surfaces). As illustrated, each sacrificial pattern 50 may be spaced apart from the vertical sidewall of an upper step that is connected with a step formed with the corresponding sacrificial pattern 50. The sacrificial pattern 50 may include an insulating material that has an etch selectivity that is different from those of the sacrificial layers 22 and the interlayer insulating layers 20. For example, the sacrificial pattern 50 may include SiCN.

Thereafter, an insulating layer 60, which covers the pre-stack PS and the sacrificial patterns 50, may be formed, and the upper surface of the insulating layer 60 may be planarized.

Referring to FIG. 7B, by forming an etch mask (not illustrated) on the insulating layer 60 and etching the insulating layer 60, the sacrificial patterns 50, and the pre-stack PS by using the etch mask, first to third holes H1 to H3 and a slit SLT may be formed.

The first hole H1 may vertically extend by passing through the step upper surface of the step portion of the pre-stack PS. The second and third holes H2 and H3 may vertically extend by passing through non-step portions of the pre-stack PS.

The slit SLT may have a line shape. The pre-stack PS may be divided by the slit SLT.

Referring to FIG. 7C, first insulating patterns DP1 may be selectively formed on the side surfaces of sacrificial layers 22, which are exposed by the first hole H1. The first insulating patterns DP1 may be selectively deposited on the sacrificial layers 22 and may be made of an insulating material that has an etch selectivity that is different from those of the sacrificial layers 22 and the sacrificial patterns 50. For example, the first insulating patterns DP1 may include SiOC.

While forming the first insulating patterns DP1, second insulating patterns DP2 may be selectively formed on the side surfaces of sacrificial layers 22, which are exposed by the second hole H2. While forming the first insulating patterns DP1, third insulating patterns DP3 may be selectively formed on the side surfaces of sacrificial layers 22, which are exposed by the third hole H3. While forming the first insulating patterns DP1, fourth insulating patterns DP4 may be selectively formed on the side surfaces of sacrificial layers 22, which are exposed by the slit SLT. The second to fourth insulating patterns DP2 to DP4 may be made of the same material as the first insulating patterns DP1.

Referring to FIG. 7D, a hard mask HM, which covers the first to third holes H1 to H3 and the slit SLT, may be formed on the insulating layer 60. The hard mask HM may cover the first to third holes H1 to H3 and the slit SLT and may partially fill the upper portions of the first to third holes H1 to H3 and the slit SLT.

Thereafter, a first opening OP1, which exposes the third hole H3, may be formed in the hard mask HM, and a support SS may be formed in the third hole H3 and the first opening OP1. The support SS may include an insulating material that has an etch selectivity that is different from those of the hard mask HM and the sacrificial layers 22.

Referring to FIG. 7E, a second opening OP2, which exposes the slit SLT, may be formed in the hard mask HM, and the fourth insulating patterns DP4 (see FIG. 7D), which are formed on the side surface of the slit SLT, may be removed.

Referring to FIG. 7F, the sacrificial layers 22 may be selectively removed, resulting in a plurality of electrode areas GR being opened. The electrode areas GR may be formed between vertically adjacent interlayer insulating layers 20 vertically and between sacrificial patterns 50 and interlayer insulating layers 20 that are vertically adjacent to the sacrificial patterns 50.

The first to third insulating patterns DP1 to DP3 may be exposed by the electrode areas GR. Since the first to third insulating patterns DP1 to DP3 are made of a material that has an etch selectivity that is different from that of the sacrificial layers 22, the first to third insulating patterns DP1 to DP3 might not be removed during a process of removing the sacrificial layers 22.

Referring to FIG. 7G, third openings OP3, which expose the first holes H1, may be formed in the hard mask HM, and sacrificial patterns 50 around the first holes H1 may be removed, resulting in a plurality of pad areas PR being opened. The pad area PR may communicate with the first hole H1 and may be expanded from the first hole H1 in a horizontal direction. The first hole H1 may communicate with the pad area PR and a gate area GR.

As the sacrificial pattern 50 around the slit SLT is removed in a process of forming the pad areas PR, a dummy pad area DPR may be formed. The dummy pad area DPR may communicate with the slit SLT and may be expanded from the slit SLT in the horizontal direction. The slit SLT may communicate with the dummy pad area DPR.

Since the first to third insulating patterns DP1 to DP3 are made of a material that has an etch selectivity that is different from that of the sacrificial patterns 50, the first to third insulating patterns DP1 to DP3 might not be removed during a process of removing the sacrificial patterns 50.

Referring to FIG. 7H, the hard mask HM may be removed. Accordingly, the first holes H1 and the second hole H2 illustrated in FIG. 7G may be exposed.

Thereafter, a second blocking insulating layer 30 may be formed along the surfaces of the gate areas GR, the pad areas PR, the dummy pad area DPR, the first holes H1, and the second hole H2, illustrated in FIG. 7G. The second blocking insulating layer 30 might not be formed between the pad area PR, the electrode area GR, and the first hole H1, which communicate with each other, and even after forming the second blocking insulating layer 30, the pad area PR, the electrode area GR, and the first hole H1 may communicate with each other.

The electrode areas GR, the pad areas PR, the first holes H1, and the second holes H2 may be filled with a conductive material, allowing for electrode portions 41 of gate electrodes 40 to be formed in the electrode areas GR, pad portions 42 of the gate electrodes 40 to be formed in the pad areas PR, row connection contacts RCT to be formed in the first holes H1, and a through contact TCT to be formed in the second hole H2.

As described above, since the electrode area GR, the pad area PR, and the first hole H1 communicate with each other, the electrode portion 41 and the pad portion 42 of the gate electrode 40 and the row connection contact RCT may be integrally formed.

Since the slit SLT has a line shape, while the first holes H1 and the second hole H2 are filled with a conductive material, the slit SLT might not be filled with the conductive material.

Referring again to FIG. 2, a sidewall insulating layer 71 may be formed on the sidewall of the slit SLT. A process of forming the sidewall insulating layer 71 may include forming an insulating material on the entire surface including the slit SLT and exposing the bottom surface of the slit SLT by etching the insulating material.

A conductive vertical contact 72 may be formed by filling the slit SLT with a doped semiconductor material. The doped semiconductor material may include an n-type impurity.

A three-dimensional memory device based on an embodiment of the disclosed technology may be provided as a peripheral under cell (PUC) structure or a peripheral over cell (POC) structure.

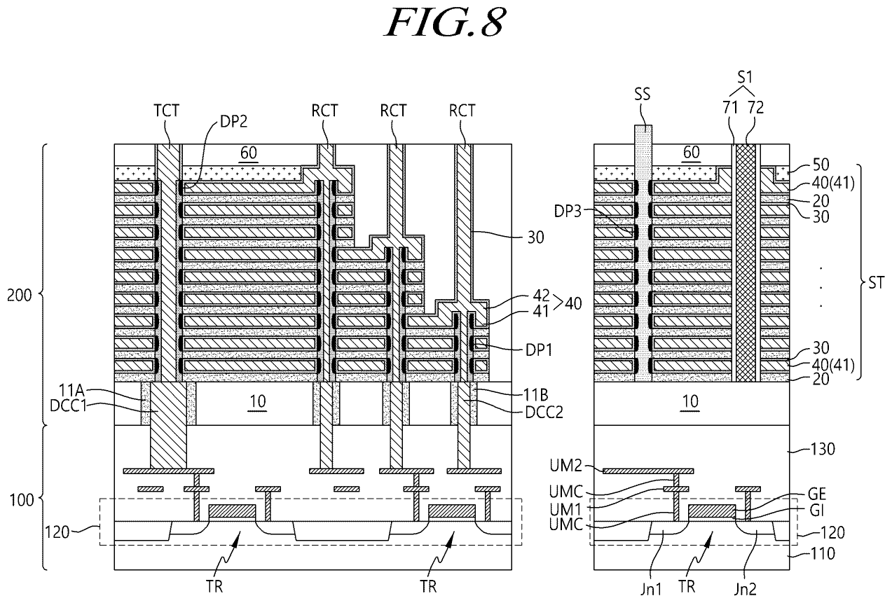

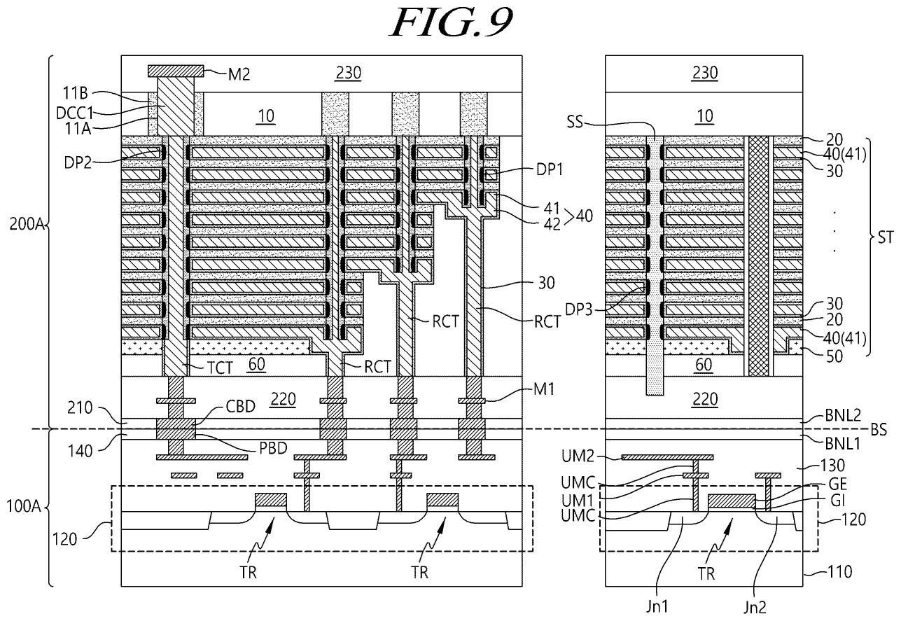

FIGS. 8 and 9 are cross-sectional views illustrating three-dimensional memory devices based on embodiments of the disclosed technology.

Referring to FIG. 8, a three-dimensional memory device based on an embodiment of the disclosed technology may have a PUC structure. In detail, the three-dimensional memory device may include a first semiconductor structure 100 and a second semiconductor structure 200, the second semiconductor structure 200 being built up on the first semiconductor structure 100. That is to say, after first forming the first semiconductor structure 100, the second semiconductor structure 200 may then be formed on the first semiconductor structure 100.

The second semiconductor structure 200 may include a memory cell array, and the first semiconductor structure 100 may include a peripheral circuit that controls the operation of the memory cell array. For example, the peripheral circuit may include a row decoder, a page buffer circuit, a voltage generator, a control circuit, etc., but the disclosure is not limited thereto.

The first semiconductor structure 100 may include a substrate 110, a peripheral circuit 120, an insulating layer 130, a plurality of lower interconnections UM1 and UM2, and a plurality of lower contacts UMC.

The substrate 110 may include at least one of a monocrystalline silicon layer, an SOI (silicon on insulator), a silicon layer formed on a silicon germanium (SiGe) layer, a monocrystalline silicon layer formed on an insulating layer, and a polysilicon layer formed on an insulating layer.

The peripheral circuit 120 may include a transistor TR. The transistor TR may include impurity areas Jn1 and Jn2, a gate insulating layer GI, and a gate electrode GE. The impurity areas Jn1 and Jn2 may be formed by doping impurities into the substrate 110. The channel area of the transistor TR may be configured between the impurity areas Jn1 and Jn2, and the gate insulating layer GI may be disposed on the channel area. The gate electrode GE may be disposed on the gate insulating layer GI. Although not illustrated, the peripheral circuit 120 may further include, in addition to the transistor TR, any active or passive component, for example, at least one of a diode, a resistor and a capacitor.

The insulating layer 130 may be disposed on the substrate 110 to cover the transistor TR.

The lower interconnections UM1 and UM2 and the lower contacts UMC may be disposed in the insulating layer 130. The lower interconnections UM1 and UM2 may include, for example, a first lower interconnection UM1 and a second lower interconnection UM2, the second lower interconnection UM2 disposed over the first lower interconnection UM1. FIG. 8 illustrates a case in which the lower interconnections UM1 and UM2 are disposed in two layers, but the embodiment of the disclosed technology is not limited thereto. Lower interconnections may be disposed in at least three layers.

The lower interconnections UM1 and UM2 may be configured to have properties that might not exhibit a process defect, for example, a hillock, at a maximum temperature (hereinafter, referred to as a ‘process critical temperature’) during a process of forming a memory cell array. In other words, as a material for the lower interconnections UM1 and UM2, a conductive material that has a heat resistance characteristic at the process critical temperature may be used. For example, the lower interconnections UM1 and UM2 may include a material that has a melting point that is higher than the process critical temperature, for example, tungsten (W). Since the lower interconnections UM1 and UM2 are formed before forming the memory cell array, the lower interconnections UM1 and UM2 may be formed using a conductive material that has a high resistivity but has a high melting point.

The peripheral circuit 120 and the lower interconnections UM1 and UM2 may be connected to each other through the lower contacts UMC.

The second semiconductor structure 200 may be disposed on the insulating layer 130 of the first semiconductor structure 100. The second semiconductor structure 200 may include the three-dimensional memory device described above with reference to FIGS. 1 to 7H.

A first conductive contact plug DCC1 may be connected to a through contact TCT. Specifically, a lower end of the first through contact TCT may be connected to the first conductive contact plug DCC1. The first conductive contact plug DCC1 may be connected to the lower interconnection UM2 by passing through an insulating pattern 11A and the insulating layer 130 and may be connected to the peripheral circuit 120 through the lower contacts UMC, the lower interconnection UM1, and the lower interconnection UM2.

A second conductive contact plug DCC2 may be connected to a row connection contact RCT. Specifically, a lower end of the row connection contact RCT may be connected to the second conductive contact plug DCC2. The second conductive contact plug DCC2 may be connected to the lower interconnection UM2 by passing through an insulating pattern 11B and the insulating layer 130 and may be connected to the peripheral circuit 120 through the lower contacts UMC, the lower interconnection UM1, and the lower interconnection UM2.

Referring to FIG. 9, a three-dimensional memory device based on an embodiment of the disclosed technology may have a POC structure. In other words, a first semiconductor structure 100A and a second semiconductor structure 200A may be fabricated on different wafers and may then be coupled by being bonded to each other.

Referring to FIG. 9, the first semiconductor structure 100A may further include a first bonding layer BNL1 compared to the first semiconductor structure 100 of FIG. 8.

In detail, the first semiconductor structure 100A may include a substrate 110, a peripheral circuit 120 that is defined on the substrate 110, the first bonding layer BNL1, and a plurality of lower interconnections UM1 and UM2 that are disposed between the substrate 110 and the first bonding layer BNL1.

An insulating layer 130 may be defined on the substrate 110 to cover the peripheral circuit 120. The plurality of lower interconnections UM1 and UM2 may be disposed in the insulating layer 130.

The lower interconnections UM1 and UM2 may include, for example, at least one of aluminum (Al) and copper (Cu). Because the lower interconnections UM1 and UM2 are formed on a separate wafer from a memory cell array, a material configuring the lower interconnections UM1 and UM2 may be selected without considering the thermal budget of a process for forming the memory cell array. Aluminum (Al), copper (Cu), or the like having a low resistivity may be selected as a material for configuring the lower interconnections UM1 and UM2 so that the lower interconnections UM1 and UM2 may have low resistances.

The first bonding layer BNL1 may include a plurality of first bonding pads PBD and a first bonding insulating pattern 140 that insulates the first bonding pads PBD from each other. The first bonding pads PBD may be connected to the lower interconnections UM2 through lower contacts UMC.

Compared to the second semiconductor structure 200 of FIG. 8, the second semiconductor structure 200A may further include a second bonding layer BNL2, insulating layers 220 and 230, and first and second upper interconnections M1 and M2.

The second bonding layer BNL2 may include a plurality of second bonding pads CBD and a second bonding insulating pattern 210, the second bonding insulating pattern 210 insulating the second bonding pads CBD from each other.

The second bonding layer BNL2 of the second semiconductor structure 200A may be bonded to the first bonding layer BNL1 of the first semiconductor structure 100A in a face-to-face manner at a bonding interface BS. The bonding interface BS may be configured between the first bonding layer BNL1 and the second bonding layers BNL2 as a result of hybrid bonding that is also referred to as direct bonding and may simultaneously configure a metal-metal bond and a dielectric-dielectric bond. At the bonding interface BS, the plurality of first bonding pads PBD and the plurality of second bonding pads CBD may be bonded to each other to configure a plurality of conductive bonds, and the first bonding insulating pattern 140 and the second bonding insulating pattern 210 may be bonded to each other to configure an insulating bond.

The first upper interconnection M1 may be disposed between the second bonding layer BNL2 and a stack ST. The disclosed technology illustrates a case where first upper interconnections M1 are disposed in one layer, but is not limited thereto. The first upper interconnections M1 may be disposed in at least two layers.

The insulating layer 230 may be disposed on a source plate 10 and insulating patterns 11A and 11B. The second upper interconnection M2 may be disposed in the insulating layer 230. A first conductive contact plug DCC1 may connect a through contact TCT and the second upper interconnection M2 by passing through the insulating pattern 11A and the insulating layer 230. Although not illustrated, the second upper interconnection M2 may include an external connection pad.

Although exemplary embodiments of the present disclosure have been described for illustrative purposes, those skilled in the art will appreciate that various modifications, additions and substitutions are possible, without departing from the scope and spirit of the present disclosure. Therefore, the embodiments disclosed above and in the accompanying drawings should be considered in a descriptive sense only and not for limiting the technological scope. The technological scope of the present disclosure is not limited by the embodiments and the accompanying drawings.

What is claimed is:

1. A three-dimensional memory device comprising:
a stack including:
a plurality of gate electrodes, each of which includes an electrode portion and a pad portion, the pad portion being disposed on one area of the electrode portion; and
a plurality of interlayer insulating layers that are stacked alternately with the plurality of gate electrodes, the stack having a connection area in which the pad portions of the plurality of gate electrodes are disposed in step shapes;
a row connection contact passing through the connection area and passing through a corresponding pad portion of a corresponding gate electrode, among the plurality of gate electrodes, thereby connecting to the corresponding pad portion of the corresponding gate electrode; and
a plurality of first insulating patterns disposed between the row connection contact and side surfaces of electrode portions of gate electrodes that face the row connection contact.

2. The three-dimensional memory device according to claim 1, wherein the plurality of first insulating patterns include SiOC.

3. The three-dimensional memory device according to claim 1, wherein each of the plurality of first insulating patterns includes a first surface that faces the electrode portion and a second surface that faces the row connection contact, and
wherein the first surface is aligned with side surfaces of interlayer insulating layers that face the row connection contact.

4. The three-dimensional memory device according to claim 1, wherein each of the plurality of first insulating patterns includes a first surface that faces the electrode portion and a second surface that faces the row connection contact, and
wherein the second surface includes a curved surface.

5. The three-dimensional memory device according to claim 1, wherein the row connection contact is formed integrally with the one gate electrode.

6. The three-dimensional memory device according to claim 1, further comprising:
a through contact passing through the stack; and
a plurality of second insulating patterns disposed on side surfaces of gate electrodes that face the through contact.

7. The three-dimensional memory device according to claim 6, wherein the plurality of second insulating patterns are made of the same material as the plurality of first insulating patterns.

8. The three-dimensional memory device according to claim 7, wherein each of the plurality of second insulating patterns includes a first surface that faces the electrode portion and a second surface that faces the through contact, and
wherein the first surface is aligned with side surfaces of interlayer insulating layers that face the through contact.

9. The three-dimensional memory device according to claim 1, further comprising:
a support passing through the stack; and
a plurality of second insulating patterns disposed on side surfaces of gate electrodes that face the support.

10. The three-dimensional memory device according to claim 9, wherein the plurality of second insulating patterns are made of the same material as the plurality of first insulating patterns.

11. The three-dimensional memory device according to claim 9, wherein each of the plurality of second insulating patterns includes a first surface that faces the electrode portion and a second surface that faces the support, and
wherein the first surface is aligned with side surfaces of interlayer insulating layers that face the support.

12. A three-dimensional memory device comprising:
a first semiconductor structure including a peripheral circuit; and
a second semiconductor structure disposed on the first semiconductor structure,
the second semiconductor structure comprising:
a source plate disposed on the first semiconductor structure;
a stack disposed on the source plate, the stack including:
a plurality of gate electrodes, each of which includes an electrode portion and a pad portion, the pad portion being disposed on one area of the electrode portion; and
a plurality of interlayer insulating layers that are stacked alternately with the plurality of gate electrodes, the stack having a connection area in which the pad portions of the plurality of gate electrodes are disposed in step shapes;
a row connection contact passing through the connection area and passing through a corresponding pad portion of a corresponding gate electrode, among the plurality of gate electrodes, thereby connecting to the corresponding pad portion of the corresponding gate electrode; and
a plurality of first insulating patterns disposed between the row connection contact and side surfaces of electrode portions of gate electrodes that face the row connection contact.

13. A three-dimensional memory device comprising:
a first semiconductor structure having a peripheral circuit and a first bonding layer including a plurality of first bonding pads that are connected to the peripheral circuit; and
a second semiconductor structure bonded to the first semiconductor structure,
the second semiconductor structure comprising:
a second bonding layer including a plurality of second bonding pads that are bonded to the plurality of first bonding pads;
a stack disposed on the second bonding layer, the stack including:
a plurality of gate electrodes, each of which includes an electrode portion and a pad portion, the pad portion being disposed on one area of the electrode portion; and
a plurality of interlayer insulating layers that are stacked alternately with the plurality of gate electrodes, the stack having a connection area in which the pad portions of the plurality of gate electrodes are disposed in step shapes;
a row connection contact passing through the connection area and passing through a corresponding pad portion of a corresponding gate electrode, among the plurality of gate electrodes, thereby connecting to the corresponding pad portion of the corresponding gate electrode; and
a plurality of first insulating patterns disposed between the row connection contact and side surfaces of electrode portions of gate electrodes that face the row connection contact.
